(19) United States
(12) Patent Application Publication
(10) Pub. No.: US 2015/0187849 A1
(43) Pub. Date: Jul. 2, 2015

(54) METHODS OF MANUFACTURING FLEXIBLE SUBSTRATES, FLEXIBLE DISPLAY DEVICES AND METHODS OF MANUFACTURING FLEXIBLE DISPLAY DEVICES

(71) Applicant: Samsung Display Co., Ltd., Yongin-City (KR)

(72) Inventors: Hayk KACHATRYAN, Hwaseong-si (KR); Hyun-Woo KOO, Hwaseong-si (KR); Kyung-Min CHOI, Seoul (KR)

(21) Appl. No.: 14/520,518

(22) Filed: Oct. 22, 2014

(30) Foreign Application Priority Data
Dec. 30, 2013 (KR) 10-2013-0166966

(51) Int. Cl. H01L 27/32; H01L 51/00; H01L 27/12; H01L 51/56

(52) U.S. Cl. CPC H01L 27/3248; H01L 51/56; H01L 51/0097; H01L 27/1274; H01L 2227/323; H01L 2251/5338; H01L 2251/556

(57) ABSTRACT

In a method of manufacturing a flexible substrate, a preliminary sacrificial layer that includes polyimide is formed on a carrier substrate. The preliminary sacrificial layer is transformed into a sacrificial layer that includes a modified polyimide. A base substrate layer that includes polyimide is formed on the sacrificial layer. A device structure is formed on the base substrate layer. A combination of the base substrate layer and the device structure is separated from the carrier substrate.

This application claims priority to Korean Patent Application No. 10-2013-0166966 filed on Dec. 30, 2013, and all the benefits accruing therefrom under 35 USC §119, the entire disclosure of which is herein incorporated by reference.

### BACKGROUND

1. Field

Exemplary embodiments relate to methods of manufacturing flexible substrates, flexible display devices and methods of manufacturing flexible display devices. More particularly, exemplary embodiments relate to methods of manufacturing flexible substrates including resin materials, flexible display devices including the flexible substrates and methods of manufacturing the flexible display devices.

2. Description of the Related Art

Flexible display devices which are foldable or bendable to have improved portability have been developed. In a flexible display device, a flexible substrate having an improved flexibility may be employed, and plastic or resin materials may be used for the flexible substrate.

### SUMMARY

However, plastic or resin materials used for a flexible substrate of a display device may have a relatively low heat-resistance, and thus may be decomposed or melted during a thermal process for forming a structure including, e.g., a thin film transistor (“TFT”) on the flexible substrate. Additionally, when the flexible substrate is detached from a carrier substrate during a manufacturing process of the display device, a surface of the flexible substrate may be damaged.

Exemplary embodiments provide a method of manufacturing a flexible substrate having improved mechanical and chemical reliability.

Exemplary embodiments provide a flexible display device including a flexible substrate with improved mechanical and chemical reliability.

Exemplary embodiments provide a method of manufacturing a flexible display device including a flexible substrate with improved mechanical and chemical reliability.

According to exemplary embodiments, there is provided a method of manufacturing a flexible substrate. In the method, a preliminary sacrificial layer including polyimide is formed on a carrier substrate. The preliminary sacrificial layer is transformed into a sacrificial layer including a modified polyimide. A base substrate layer comprising is formed on the sacrificial layer. A device structure is formed on the base substrate layer. A combination of the base substrate layer and the device structure is separated from the carrier substrate.

In exemplary embodiments, in forming the preliminary sacrificial layer, a polyimide precursor composition may be coated on the carrier substrate to form a first coating layer. A thermal curing process may be performed on the first coating layer to form the preliminary sacrificial layer.

In exemplary embodiments, the thermal curing process may be performed at a temperature ranging from about 50 degrees Celsius (° C.) to about 300° C.

In exemplary embodiments, a heat treatment may be performed on the preliminary sacrificial layer at a temperature ranging from about 300° C. to about 900° C. so that the preliminary sacrificial layer may be transformed into the sacrificial layer.

In exemplary embodiments, the heat treatment may be performed at a temperature ranging from about 300° C. to about 600° C.

In exemplary embodiments, the sacrificial layer may have a brittleness and a hardness greater than those of the preliminary sacrificial layer.

In exemplary embodiments, the sacrificial layer may have an oxygen content greater than that of the preliminary sacrificial layer.

In exemplary embodiments, the sacrificial layer may have a coefficient of thermal expansion (“CTE”) different from that of the preliminary sacrificial layer.

In exemplary embodiments, the sacrificial layer may have a negative CTE and the preliminary sacrificial layer may have a positive CTE.

In exemplary embodiments, in forming the base substrate layer, a second polyimide precursor composition may be coated on the sacrificial layer to form a second coating layer. The second coating layer may be thermally cured at a temperature ranging from about 50° C. to about 300° C.

In exemplary embodiments, in forming the device structure, an active layer may be formed on the base substrate layer. A crystallization process may be performed on the active layer.

In exemplary embodiments, the crystallization process may be performed at a temperature ranging from about 200° C. to about 500° C.

According to exemplary embodiments, there is provided a flexible display device. The flexible display device includes a base substrate layer including polyimide, an electronic device on the base substrate layer, a light emitting structure electrically connected to the electronic device on the base substrate layer, and a modified polyimide layer on a lower surface of the base substrate layer.

In exemplary embodiments, the modified polyimide layer may have a color darker than that of the base substrate layer.

In exemplary embodiments, the modified polyimide layer may have a brittleness, a hardness and an oxygen content greater than those of the base substrate layer. The modified polyimide layer may have a CTE less than that of the base substrate layer.

In exemplary embodiments, the electronic device may include a thin film transistor that includes an active layer.

In exemplary embodiments, the light emitting structure may include a first electrode electrically connected to the thin film transistor, an organic light emitting layer on the first electrode and a second electrode on the organic light emitting layer.

According to exemplary embodiments, there is provided a method of manufacturing a flexible display device. In the method, a preliminary sacrificial layer including polyimide is formed on a carrier substrate. The preliminary sacrificial layer is transformed into a sacrificial layer including a modified polyimide. A base substrate layer including polyimide is formed on the sacrificial layer. An electronic device is formed on the base substrate layer. A light emitting structure electrically connected to the electronic device is formed on the base substrate layer. A combination of the base substrate layer, the electronic device and the light emitting structure is separated from the carrier substrate.

In exemplary embodiments, a portion of the sacrificial layer may be maintained on a lower surface of the base substrate layer by the separating the combination of the base substrate layer, the electronic device and the light emitting structure from the carrier substrate.

In exemplary embodiments, in transforming the preliminary sacrificial layer into the sacrificial layer, a heat treatment may be performed on the preliminary sacrificial layer at a temperature ranging from about 300° C. to about 900° C. In forming the electronic device on the base substrate layer, a preliminary active layer may be formed on the base substrate layer. A crystallization process may be performed on the preliminary active layer at a temperature ranging from about 200° C. to about 500° C. to form an active layer.

According to one or more exemplary embodiment, a polyimide having a relatively high heat resistance may be used as a material of a flexible substrate. A sacrificial layer including a modified polyimide may be formed between a carrier substrate and the flexible substrate. The sacrificial layer may be formed by performing a heat treatment on a polyimide substantially the same as that of the flexible substrate. Thus, processes for manufacturing the flexible substrate may be simplified. Further, the flexible substrate may be easily separated or detached from the carrier substrate by mechanical or chemical differences between the sacrificial layer and the flexible substrate.

### BRIEF DESCRIPTION OF THE DRAWINGS

Exemplary embodiments will be more clearly understood from the following detailed description taken in conjunction with the accompanying drawings. FIGS. 1 to 14 represent non-limiting, exemplary embodiments as described herein:

FIGS. 1 to 5C are cross-sectional views illustrating an exemplary embodiment of a method of manufacturing a flexible substrate in accordance with the invention;

FIGS. 6A and 6B are cross-sectional views illustrating exemplary embodiments of a flexible display device in accordance with the invention;

FIGS. 7 to 13C are cross-sectional views illustrating an exemplary embodiment of a method of manufacturing a flexible display device in accordance with the invention; and

FIG. 14 is a graph showing a mass reduction in percent (%) of a sacrificial layer according to a temperature change in degrees Celsius (° C.).

### DETAILED DESCRIPTION

Various exemplary embodiments will be described more fully hereinafter with reference to the accompanying drawings, in which exemplary embodiments are shown. The invention may, however, be embodied in many different forms and should not be construed as limited to the exemplary embodiments set forth herein. Rather, these exemplary embodiments are provided so that this disclosure will be thorough and complete, and will fully convey the scope of the invention to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

Spatially relative terms, such as “lower,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” relative to other elements or features would then be oriented “upper” relative to the other elements or features. Thus, the exemplary term “lower” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the invention will be described in detail with reference to the accompanying drawings.

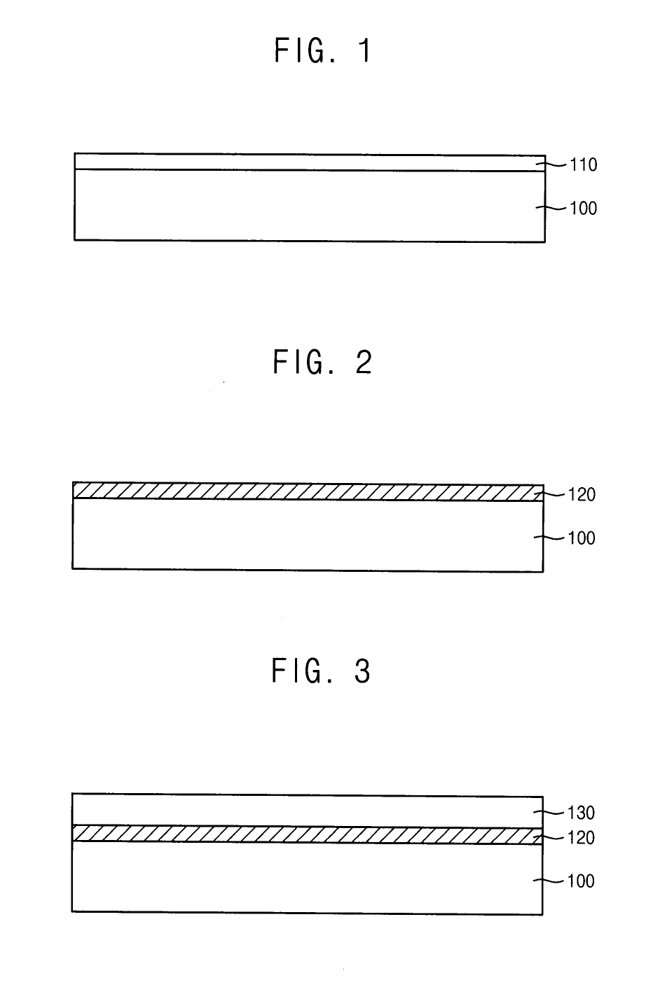

FIGS. 1 to 5C are cross-sectional views illustrating an exemplary embodiment of a method of manufacturing a flexible substrate in accordance with the invention.

Referring to FIG. 1, a preliminary sacrificial layer 110 may be formed (e.g., provided) on a carrier substrate 100.

The carrier substrate 100 may support a base substrate layer 130 (FIG. 3) during a formation of the flexible substrate. The carrier substrate 100 may include, e.g., a glass substrate or a metal substrate.

In exemplary embodiments, a liquid polyimide precursor composition may be coated on the carrier substrate 100 to form a first coating layer. The first coating layer may be thermally cured to form the preliminary sacrificial layer 110. The first coating layer may be formed by, e.g., a spin coating process.

The polyimide precursor composition may be prepared by dissolving a polyimide precursor in an organic solvent. The polyimide precursor may include polyamic acid (“PAA”). Polyamic acid may be synthesized through a polycondensation of diamine and dianhydride.

The organic solvent may include, e.g., N-Methyl-2-Pyrrolidone (“NMP”), dimethyl formamide (“DMF”), tetrahydrofuran (“THF”), triethylamine (“TEA”), ethylacetate, dimethyl sulfoxide (“DMSO”) or an ethylene-eglycol based ether solvent. These may be used alone or in a combination thereof.

The polyimide precursor composition may further include a silane coupling agent. The silane coupling agent may improve coating properties and adhesion of the preliminary sacrificial layer 110. The silane coupling agent may include, e.g., aminopropyltriethoxysilane, diethylenetriaminopropyltrimethoxysilane, cyclohexylaminopropyltrimethoxysilane, hexanediaminomethyltriethoxysilane, anilinomethyltrimethoxysilane, diethylaminomethyltriethoxysilane, bis(triethoxysilylpropyl)tetrasulfide, mercaptopropyltrimethoxysilane, 3-thiocyanopropyltriethoxysilane, glycidoxypropyltrimethoxysilane, methacryloxypropyltrimethoxysilane, chloropropyltrimethoxysilane, vinyltrimethoxysilane, etc. These may be used alone or in a combination thereof.

The polyimide precursor composition may further include additives, non-limiting examples of which include e.g., a cross-linking agent, a thermal curing accelerator, etc.

The first coating layer may be thermally cured to be transformed into the preliminary sacrificial layer 110. In exemplary embodiments, the thermal curing process may be performed at a temperature ranging from about 50 degrees Celsius (° C.) to about 300° C.

The organic solvent may be vaporized from the first coating layer by the thermal curing process to cause imidization. Accordingly, the preliminary sacrificial layer 110 including polyimide may be attached to the carrier substrate 100.

Referring to FIG. 2, a heat treatment process may be performed on the preliminary sacrificial layer 110 to form a sacrificial layer 120.

In exemplary embodiments, the sacrificial layer 120 may include a modified polyimide. Chemical structures and/or compositions of polyimide in the preliminary sacrificial layer 110 may be changed to create the modified polyimide.

In exemplary embodiments, the heat treatment process may be performed at a temperature ranging from about 300° C. to about 900° C. If the temperature for the heat treatment process is less than about 300° C., the modified polyimide may substantially not be created. If the temperature for the heat treatment process exceeds about 900° C., polyimide in the preliminary sacrificial layer 110 may be substantially decomposed to damage the preliminary sacrificial layer 110.

In one exemplary embodiment, the heat treatment process may be performed at a temperature ranging from about 300° C. to about 600° C. In one exemplary embodiment, the heat treatment process may be performed at a temperature ranging from about 450° C. to about 600° C. The temperature of about 450° C. may substantially correspond to a critical temperature at which a structure of the preliminary sacrificial layer 110 is substantially changed, or polyimide is transformed into the modified polyimide.

The heat treatment process may be performed in an air or an oxygen atmosphere. Thus, the preliminary sacrificial layer 110 may be substantially oxidized or combusted, so that the sacrificial layer 120 may be formed.

In exemplary embodiments, the sacrificial layer 120 may have mechanical, chemical and/or physical properties different from those of the preliminary sacrificial layer 110.

In an exemplary embodiment, for example, the sacrificial layer 120 may have a brittleness and a hardness greater than those of the preliminary sacrificial layer 110. Thus, the sacrificial layer 120 may be more fragile or more vulnerable to cracks than the preliminary sacrificial layer 110, when exposed to the same mechanical stress, e.g., tension.

The sacrificial layer 120 may have an oxygen content greater than that of the preliminary sacrificial layer 110. Additionally, the sacrificial layer 120 may have a coefficient of thermal expansion (“CTE”) different from that of the preliminary sacrificial layer 110. In exemplary embodiments, the sacrificial layer 120 may have a negative CTE, and the preliminary sacrificial layer 110 may have a positive CTE.

The sacrificial layer 120 may have a different color from that of the preliminary sacrificial layer 110 by an oxidation or a combustion. The sacrificial layer 120 may have a darker color than that of the preliminary sacrificial layer 110. In an exemplary embodiment, for example, the sacrificial layer 120 may have a dark yellow color or a dark brown color, and the preliminary sacrificial layer 110 may be substantially transparent or have essentially no color.

A mass reduction may occur in the preliminary sacrificial layer 110 by the heat treatment process, so that a mass of the sacrificial layer 120 may be lower than that of the preliminary sacrificial layer 110.

Referring to FIG. 3, a base substrate layer 130 may be formed on the sacrificial layer 120. In exemplary embodiments, the base substrate layer 130 may be formed by a process substantially the same as or similar to that of forming the preliminary sacrificial layer 110.

In an exemplary embodiment, for example, a polyimide precursor composition may be coated on the sacrificial layer 120 to form a second coating layer. The second coating layer may be thermally cured to obtain the base substrate layer 130 including polyimide. The thermal curing process may be performed at a temperature ranging from about 50° C. to about 300° C.

In exemplary embodiments, the base substrate layer 130 may be formed using flexible polyimide so that the base substrate layer 130 may be provided as the flexible substrate. Polyimide may have a relatively high heat resistance compared to other resin materials, and thus polyimide may maintain a structure thereof at a relatively high temperature. Therefore, the base substrate layer 130 may maintain a mechanical stability while performing a device process thereon as described below.

In exemplary embodiments, the base substrate layer 130 may be formed using a polyimide-based material substantially similar to that of the sacrificial layer 120. Thus, the base substrate layer 130 may be uniformly formed on the sacrificial layer 120 with a high affinity thereto.

In an exemplary embodiment, for example, carbon-oxygen bond structures including, e.g., a carbonyl bond (C═O), an ether bond, an ester bond (O—C═O), a peroxy bond (C—O—O), a carbonate bond (CO₃), etc., may be distributed in an upper portion of the sacrificial layer 120 due to the combustion and/or the oxidation. If polyimide precursors such as polyamic acid are coated on a surface of the sacrificial layer 120, carbon-oxygen bond structures including, e.g., carbonyl bonds of polyamic acid may form a weak interaction with the sacrificial layer 120. Accordingly, the base substrate layer 130 having uniform compositions and thickness may be formed on the substantially whole surface of the sacrificial layer 120.

The base substrate layer 130 may have mechanical and/or chemical properties substantially the same as or similar to those of the preliminary sacrificial layer 110. Thus, the base substrate layer 130 may have mechanical and/or chemical properties substantially different from those of the sacrificial layer 120.

As described above, the sacrificial layer 120 may have the hardness and the brittleness greater than those of the base substrate layer 130, and may have the oxygen content higher than that of the base substrate layer 130. Further, the sacrificial layer 120 may have a different CTE from that of the base substrate layer 130. In an exemplary embodiment, for example, the sacrificial layer 120 may have a negative CTE and the base substrate layer 130 may have a positive CTE.

Additionally, the color of the sacrificial layer 120 may be substantially darker than that of the base substrate layer 130. In an exemplary embodiment, for example, the sacrificial layer 120 may have the substantially dark yellow color or dark brown color, and the base substrate layer 130 may be substantially transparent or have essentially no color.

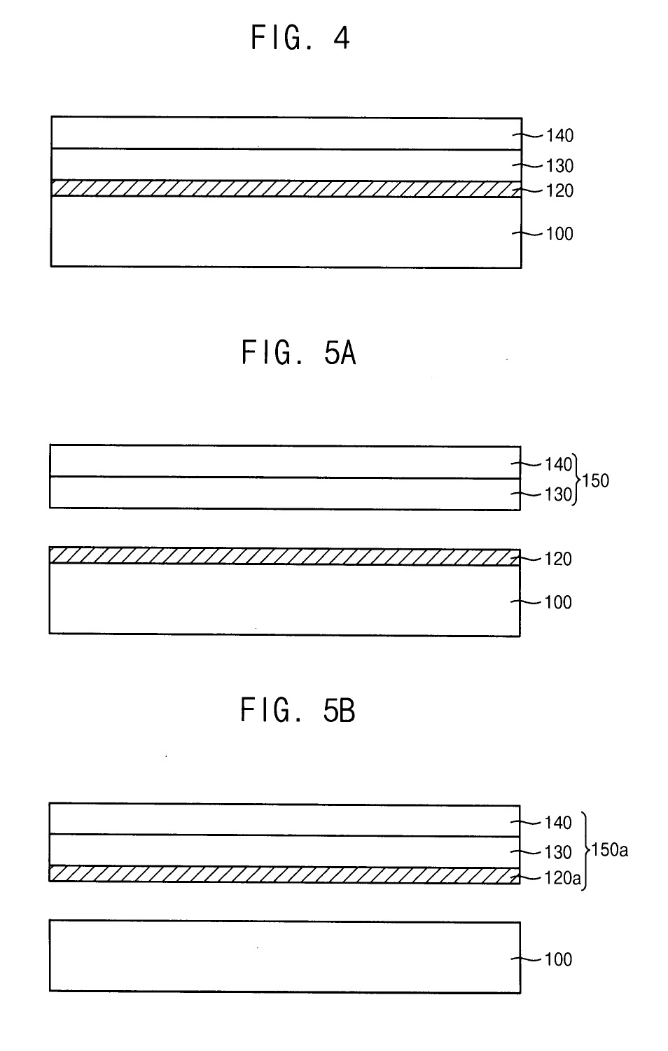

Referring to FIG. 4, a device structure 140 may be formed on the base substrate layer 130 by the aforementioned device process. The device structure 140 may include, e.g., an electronic device and/or a wiring structure, and may further include an insulation layer covering the electronic device and/or the wiring structure.

The electronic device may include various structures depending on the use of the flexible substrate. In an exemplary embodiment, for example, where the flexible substrate is applied to a semiconductor system, the electronic device may include a semiconductor device containing silicon or germanium. Where the flexible substrate is applied to a display device, the electronic device may include a thin film transistor (“TFT”).

The TFT may include an amorphous silicon layer, a polysilicon layer or an oxide semiconductor layer as an active layer. Where the active layer includes the amorphous silicon layer or the polysilicon layer, a crystallization process using a heat or a laser may be performed on the active layer. The crystallization process may include, e.g., a low temperature polycrystalline silicon (“LTPS”) process.

A process temperature for the LTPS process may be controlled so that the crystallization of the active layer may occur, however, the base substrate layer 130 may not be damaged or modified. In exemplary embodiments, the LTPS process may be performed at a temperature ranging from about 200° C. to about 500° C. If the temperature for the LTPS process is less than about 200° C., the active layer may not be sufficiently crystallized. If the temperature for the LTPS process exceeds about 500° C., polyimide in the base substrate layer 130 may be damaged or modified to result in a loss of flexibility, and the base substrate layer 130 may not be easily detached from the sacrificial layer 120.

In one exemplary embodiment, the LTPS process may be performed at a temperature ranging from about 200° C. to about 450° C.

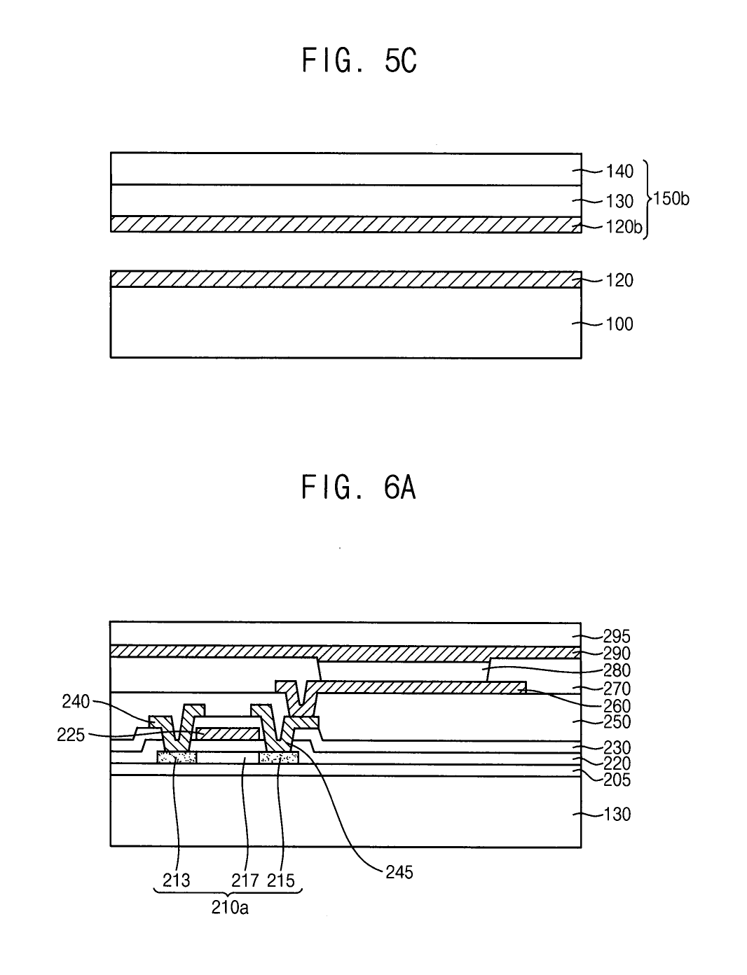

Referring to FIGS. 5A to 5C, the base substrate layer 130 and elements thereon, may be separated or detached from the carrier substrate 100. Accordingly, a flexible substrate 150 collectively including the base substrate layer 130 and the device structure 140 formed thereon may be obtained.

As illustrated in FIG. 5A, the base substrate layer 130 may be detached from the sacrificial layer 120. For detaching the base substrate layer 230 from the sacrificial layer 120, the base substrate layer 130 having the elements thereon and the sacrificial layer 120 may be fixed by a holding device, the base substrate layer 130 having the elements thereon may be pulled using, e.g., a vacuum absorber or a manpower to be detached from the sacrificial layer 120.

As described above, the sacrificial layer 120 may include the modified polyimide to have the brittleness and the hardness greater than those of the base substrate layer 130, and have the CTE different from the base substrate layer 130. While the device process including, e.g., a thermal curing process or the LTPS process are performed, a stress may be converged at an interface of the base substrate layer 130 and the sacrificial layer 120 due to a CTE difference therebetween. Thus, the base substrate layer 130 may be easily detached or separated from the sacrificial layer 120 manually.

As illustrated in FIG. 5B, the sacrificial layer 120 may be detached or separated from the carrier substrate 100. Where the sacrificial layer 120 is separated from the carrier substrate 100, a flexible substrate 150a may collectively include the base substrate layer 130, the device structure 140 formed on an upper surface thereof, and a modified polyimide layer 120a formed on a lower surface thereof.

As described above, the preliminary sacrificial layer 110 may be transformed into the sacrificial layer 120 by a chemical modification of polyimide. Thus, an adhesion between the sacrificial layer 120 and the carrier substrate 100 may become weakened. The sacrificial layer 120 and the base substrate layer 130 may contain the polyimide-based material in common, thereby to be combined with each other by a weak interaction. The adhesion between the sacrificial layer 120 and the carrier substrate 100 may be less than the interaction between the sacrificial layer 120 and the base substrate layer 130.

Accordingly, when the carrier substrate 100 is fixed and the base substrate layer 130 is pulled mechanically or manually, the sacrificial layer 120 may be entirely detached from the carrier substrate 100 while maintaining the weak interaction with the base substrate layer 130.

As illustrated in FIG. 5C, when the base substrate 130 is detached from the carrier substrate 100, a portion of the sacrificial layer 120 may be maintained on the carrier substrate 100 and a remaining portion of the sacrificial layer 120 may be detached from the carrier substrate 100 together with the base substrate layer 130.

Accordingly, a flexible substrate 150b may collectively include the base substrate layer 130, the device structure 140 formed on an upper surface thereof, and a modified polyimide layer 120b formed on a lower surface thereof.

As described with reference to FIGS. 5B and 5C, at least a portion of the sacrificial layer 120 may be detached from the carrier substrate 100 together with the base substrate layer 130 to be included in the flexible substrate 150a and 150b as the modified polyimide layer 120a and 120b, respectively. Thus, the sacrificial layer 120 may be formed to have a relatively thin cross-sectional thickness so that flexible properties of the flexible substrate 150a and 150b may not be reduced or damaged. In one exemplary embodiment, the sacrificial layer 120 may have a cross-sectional thickness less than about 1 micrometer (μm).

According to exemplary embodiments, the base substrate layer 130 of the flexible substrate may be formed using polyimide to have a flexibility. Polyimide may have a heat resistance greater than that of other polymer resin materials, so that mechanical or structural stability of the base substrate layer 130 may be maintained during or after the device process, e.g., the LTPS process. Thus, the flexibility of the flexible substrate may be maintained even after the device process.

The base substrate layer 130 may be separated or detached easily from the carrier substrate 100 due to the sacrificial layer 120 including the modified polyimide and being interposed between the base substrate layer 130 and the carrier substrate 100. Therefore, an additional detach process, e.g., a laser lift process may be omitted, so that damage from the detach process of the base substrate layer 130 and/or the device structure 140 may be avoided.

The sacrificial layer 120 may be formed from polyimide having the relatively high heat resistance as described above. Thus, an outgassing phenomenon that may occur from the other polymer resin materials by a heat treatment may be reduced or effectively prevented.

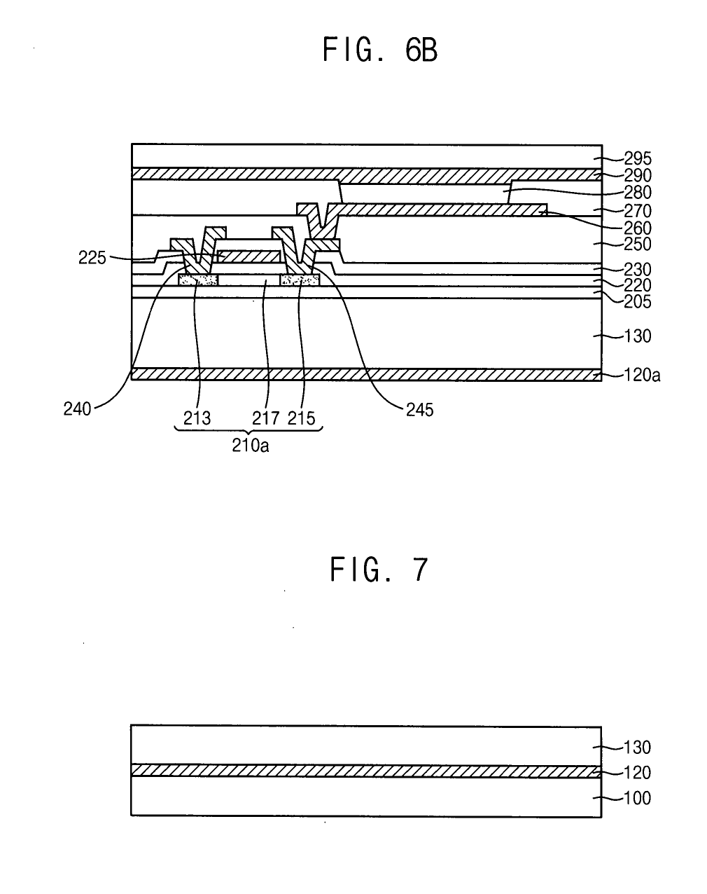

FIGS. 6A and 6B are cross-sectional views illustrating exemplary embodiments of a flexible display device in accordance with the invention.

FIGS. 6A and 6B illustrate an organic light emitting display (“OLED”) device including a flexible base substrate layer. Alternatively, exemplary embodiments of the flexible display device in accordance with the invention may have a structure of a liquid crystal display (“LCD”) device.

Detailed description on elements substantially the same as or similar to those illustrated with reference to FIGS. 1 to 5C may be omitted, and like reference numerals are used to indicate the elements.

Referring to FIGS. 6A and 6B, the flexible display device may include a buffer layer 205, an active layer 210a, a gate insulation layer 220, a gate electrode 225, a first insulating interlayer 230, a source electrode 240, a drain electrode 245 and a second insulating interlayer 250, disposed on a base substrate layer 130. An electronic device such as a switching device may be defined by the active layer 210a, the gate insulation layer 220, the gate electrode 225, the source electrode 240 and the drain electrode 245.

A light emitting structure may be disposed on the second insulating interlayer 250. The light emitting structure may include a first electrode 260, a pixel defining layer (“PDL”) 270, an organic light emitting layer (“EML”) 280 and a second electrode 290. The light emitting structure may be electrically connected to the electronic device. In an exemplary embodiment, for example, the first electrode 260 and the drain electrode 245 may be electrically connected to each other. An encapsulation layer 295 may be further disposed on the light emitting structure.

The base substrate layer 130 may include a flexible polymer material. In exemplary embodiments, the base substrate layer 130 may include polyimide.

The buffer layer 205 may be disposed on the base substrate layer 130 to prevent impurities, e.g., an organic gas from being diffused from or into the base substrate layer 130. Additionally, a planarity of the base substrate layer 130 may be improved by the buffer layer 205, and a stress imposed on the base substrate layer 130 by a formation of structures such as the gate electrode 225 during a manufacturing process may be reduced by the buffer layer 205. The buffer layer 205 may include, e.g., silicon oxide (SiOx), silicon nitride (SiNx) or silicon oxynitride (SiOxOy). These may be used alone or in a combination thereof.

The active layer 210a may be disposed on the buffer layer 205. The active layer 210a may include, e.g., polysilicon. A source region 213 and a drain region 215 including p-type or n-type impurities may be formed at both ends of the active layer 210a. A portion of the active layer 210a between the source region 213 and the drain region 215 may be defined as a channel region 217 through which charges or ions are transferred.

The gate insulation layer 220 covering the active layer 210a may be disposed on the buffer layer 205, and the gate electrode 225 may be disposed on the gate insulation layer 220.

The gate insulation layer 220 may include an insulation material, e.g., silicon oxide, silicon nitride or silicon oxynitride. The gate insulation layer 220 may have a single-layered structure or a multi-layered structure including the insulation materials. The gate insulation layer 220 may have a protruded or a stepped portion at a region covering the active layer 210a as illustrated in FIGS. 6A and 6B, taken with reference to a common element such as the base substrate layer 130. Alternatively, the gate insulation layer 220 may have a substantially leveled or even upper surface taken with reference to a common element such as the base substrate layer 130.

The gate electrode 225 may be substantially superimposed over the channel region 217 of the active layer 210a. The gate electrode 225 may be electrically connected to a gate line (not illustrated) of the flexible display device.

The gate electrode 225 may include a metal, an alloy or a metal nitride. In an exemplary embodiment, for example, the gate electrode 225 may include the metal such as aluminum (Al), silver (Ag), tungsten (W), copper (Cu), nickel (Ni), chrome (Cr), molybdenum (Mo), titanium (Ti), platinum (Pt), tantalum (Ta), neodymium (Nd) and scandium (Sc), the alloy thereof or the nitride thereof. These may be used alone or in a combination thereof. Alternatively, the gate electrode 225 may include a transparent conductive material, e.g., indium tin oxide (“ITO”), indium zinc oxide (“IZO”) or aluminum doped zinc oxide (“AZO”). The gate electrode 225 may have a multi-layered structure including at least two materials among the metal, the alloy, the metal nitride and the transparent conductive material

A driving transistor of the flexible display device may be defined by the active layer 210a, the gate insulation layer 220 and the gate electrode 225.

The first insulating interlayer 230 covering the gate electrode 225 may be disposed on the gate insulation layer 220. The first insulating interlayer 230 may include an insulation material, e.g., silicon oxide, silicon nitride or silicon oxynitride. The first insulating interlayer 230 may have a single-layered structure or a multi-layered structure including the insulation materials. The first insulating interlayer 230 may have protruded or stepped portions at regions covering the active layer 210a and the gate electrode 225 as illustrated in FIGS. 6A and 6B. Alternatively, the first insulating interlayer 230 may have a substantially leveled or even upper surface.

The source electrode 240 and the drain electrode 245 may be electrically connected to the source region 213 and the drain region 215, respectively, through openings defined in the first insulating interlayer 230 and the gate insulation layer 220. The source electrode 240 and the drain electrode 245 may include a metal such as Al, Ag, W, Cu, Ni, Cr, Mo, Ti, Pt, Ta, Nd, Sc, etc., an alloy of these metals or a nitride of the metal. Alternatively, the source and drain electrodes 240 and 245 may include a transparent conductive material, e.g., ITO, IZO or AZO.

The source electrode 240 may be electrically connected to a data line (not illustrated) of the flexible display device. A plurality of the data lines and the gate lines may be arranged to cross each other in the flexible display device. In one exemplary embodiment, an intersection region of the data lines and the gate lines may be defined as a pixel region, but the invention is not limited thereto. The driving transistor may be disposed in each pixel region of the flexible display device.

The second insulating interlayer 250 covering the source and drain electrodes 240 and 245 may be disposed on the first insulating interlayer 230. The second insulating interlayer 250 may include an insulation material, e.g., silicon oxide, silicon nitride or silicon oxynitride. The second insulating interlayer 250 may have a single-layered structure or a multi-layered structure including the insulation materials. The second insulating interlayer 250 may have a substantially leveled or even upper surface to serve as a planarization layer of the flexible display device.

The first electrode 260 may be electrically connected to the drain electrode 245 through openings defined in the second insulating interlayer 250. The first electrode 260 may include a transparent conductive material, e.g., ITO, IZO or AZO, zinc oxide, tin oxide, etc. Alternatively, the first electrode 260 may include a metal such as Al, Ag, W, Cu, Ni, Cr, Mo, Ti, Pt, Ta, Nd, Sc, etc., an alloy of these metals or a nitride of the metal. The first electrode 260 may serve as a pixel electrode and/or an anode of the flexible display device.

The PDL 270 may be disposed on the second insulating interlayer 250 to cover peripheral portions of the first electrode 260. The PDL 270 may define the pixel region of the flexible display device. An area of the pixel electrode 260 not covered by the PDL 270 may substantially correspond to the pixel region. The PDL 270 may include a photosensitive material such as polyimide resin, acryl resin or benzocyclobutene (“BCB”). Alternatively, the PDL 270 may include a non-photosensitive organic material or an inorganic material such as carbon black.

The EML 280 may be disposed on a sidewall of the PDL 270 at an opening defined in the PDL 270 and on the first electrode 260 exposed by the opening defined in the PDL 270. The second electrode 290 may be disposed on the PDL 270 and the EML 280. Holes or electrons generated by voltages from the first and second electrodes 260 and 290 may be combined in the EML 280 to form excitons. When the excitons are transferred to a ground state, a light may be emitted.

In one exemplary embodiment, a hole transport layer (“HTL”) (not illustrated) may be further disposed between the first electrode 260 and the EML 280. Further, an electron transport layer (“ETL”) (not illustrated) may be disposed between the EML 280 and the second electrode 290.

The EML 280 may include a light emitting material for generating different colors of light, for example, a red color of light, a green color of light or a blue color of light. In one exemplary embodiment, the EML 280 may include a combination of light emitting materials for generating a white color of light.

The HTL may include a hole transport material, for example, 4,4′-bis[N-(1-naphthyl)-N-phenylamino]biphenyl (“NPB”), 4,4′-bis[N-(3-methylphenyl)-N-phenylamino]biphenyl (“TPD”), N,N′-di-[(1-naphthyl)-N,N′-diphenyl]-1,1′-biphenyl)-4,4′-diamine (“NPD”), N-phenylcarbazole, polyvinylcarbazole or a combination thereof.

The ETL may include an electron transport material, for example, tris(8-quinolinolato)aluminum (“Alq3”), 2-(4-biphenylyl)-5-(4-tert-butylphenyl)-1,3,4-oxadiazole (“PBD”), bis(2-methyl-8-quinolinolato)-(4-phenylphenolato)aluminum (“Balq”), bathocuproine (“BCP”) or a combination thereof.

The second electrode 290 may include a metal such as lithium (Li), calcium (Ca), lithium fluoride/calcium (LiF/Ca), LiF/Al, Al, Mg, Ag, Cr, W, Mo or Ti and an alloy thereof. In one exemplary embodiment, the second electrode 290 may include a transparent conductive material such as ITO, IZO, AZO, tin oxide or zinc oxide. The second electrode 290 may serve as a cathode of the flexible display device.

The second electrode 290 may be disposed continuously on a substantially whole surface of the base substrate layer 130 to form a single, unitary, indivisible unit and serve as a common electrode of the flexible display device. Alternatively, the second electrode 290 may be patterned in each pixel, to form discrete units. Where the second electrode 290 is a discrete unit, the second electrode 290 may be confined within the sidewalls of the PDL 270 together with the EML 280.

An encapsulation layer 295 may be disposed on the second electrode 290 to protect the light emitting structure. The encapsulation layer 295 may include a flexible polymer resin material, e.g., polyimide.

Referring to FIG. 6B, in one exemplary embodiment, a modified polyimide layer 120a may be disposed on a lower surface of the base substrate layer 130.

The modified polyimide layer 120a may have different mechanical, physical and/or chemical properties from those of the base substrate layer 130.

In an exemplary embodiment, for example, the modified polyimide layer 120a may have a brittleness, a hardness and an oxygen content greater than those of the base substrate layer 130. Additionally, the modified polyimide layer 120a may have a smaller CTE than that of the base substrate layer 130. The modified polyimide layer 120a may have a darker color than that of the base substrate layer 130.

The modified polyimide layer 120a may cover a lower portion of the base substrate layer 130 to serve as a substantially passivation layer. The modified polyimide layer 120a may protect the base substrate layer 130 from damage by an external environment. The modified polyimide layer 120a may have a relatively thin cross-sectional thickness less than about 1 μm not to deteriorate a flexibility of the flexible display device.

FIGS. 7 to 13C are cross-sectional views illustrating an exemplary embodiment of a method of manufacturing a flexible display device in accordance with the invention. Detailed descriptions on processes and/or materials substantially the same as or similar to those illustrated with reference to FIGS. 1 to 5C are omitted.

Referring to FIG. 7, processes substantially the same as or similar to those illustrated with reference to FIGS. 1 to 3 may be performed. Accordingly, a sacrificial layer 120 may be formed on a carrier substrate 100, and a base substrate layer 130 may be formed on the sacrificial layer 120.

In exemplary embodiments, a preliminary sacrificial layer may be formed using polyimide, and a heat treatment may be performed on the preliminary sacrificial layer at a temperature ranging from about 300° C. to about 600° C., or from about 450° C. to about 600° C. to obtain the sacrificial layer 120. The base substrate layer 130 may be formed by coating a polyimide precursor composition including, e.g., polyamic acid, and thermally curing the coated composition. The sacrificial layer 120 may include a modified polyimide having different mechanical, physical and/or chemical properties from polyimide of the base substrate layer 130 as described above.

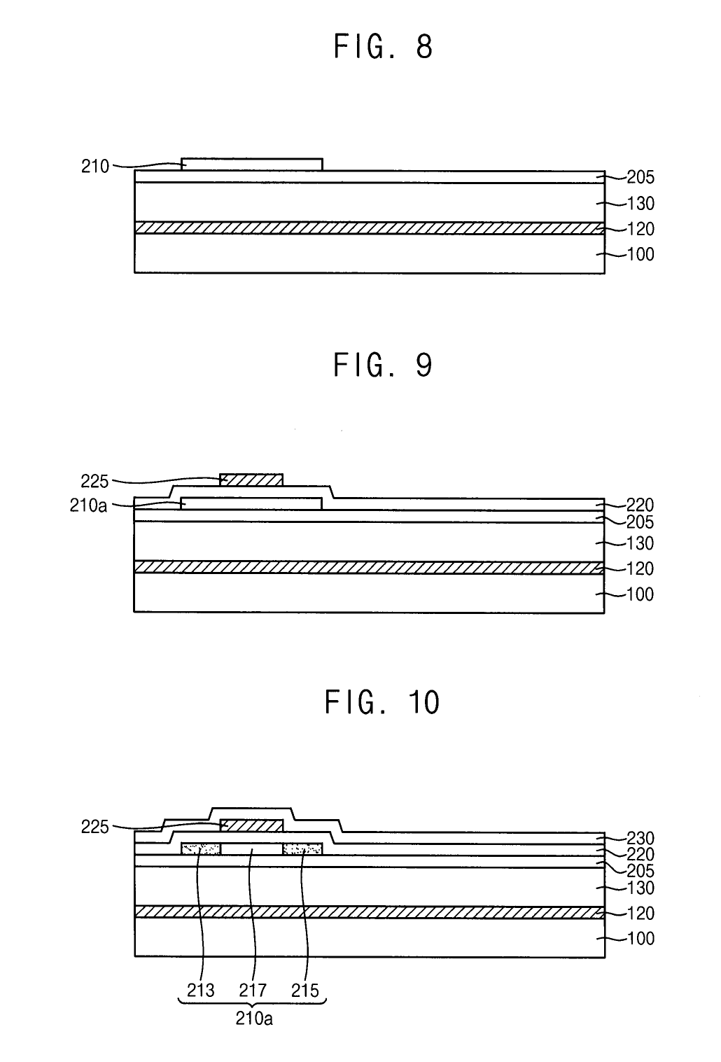

Referring to FIG. 8, a buffer layer 205 may be formed on the base substrate layer 130, and a preliminary active layer 210 may be formed on the buffer layer 205.

The buffer layer 205 may be formed using a silicon compound, e.g., silicon oxide, silicon nitride or silicon oxynitride by, e.g., a chemical vapor deposition (“CVD”) process, a plasma enhanced chemical vapor deposition (“PECVD”) process, a high density plasma-chemical vapor deposition (“HDP-CVD”) process, a spin coating process, etc.

A semiconductor layer including, e.g., amorphous silicon may be formed on the buffer layer 205, and the semiconductor layer may be patterned to obtain the preliminary active layer 210. The semiconductor layer may be formed by a CVD process, a PECVD process, a sputtering process, an atomic layer deposition (“ALD”) process, etc.

Referring to FIG. 9, the preliminary active layer 210 may be transformed into an active layer 210a including polysilicon by a crystallization process.

The crystallization process may include, e.g., a laser annealing process or an LTPS process. The LTPS process may be performed at a temperature ranging from about 200° C. to about 500° C. In one exemplary embodiment, the LTPS process may be performed at a temperature ranging from about 200° C. to about 450° C.

In exemplary embodiments, the base substrate layer 130 and the sacrificial layer 120 may include a polyimide-based material stable in the above temperature range. Thus, a flexibility of the base substrate layer 130 may be maintained even after the LTPS process.

A gate insulation layer 220 covering the active layer 210a may be formed on the buffer layer 205, and a gate electrode 225 may be formed on the gate insulation layer 220 to be superimposed over the active layer 210a.

The gate insulation layer 220 may be formed using an insulation material, e.g., silicon oxide, silicon nitride or silicon oxynitride. The gate insulation layer 220 may have a single-layered structure or a multi-layered structure including, e.g., a silicon oxide layer and a silicon oxynitride layer. The gate insulation layer 220 may be obtained by a CVD process, a PECVD process, a spin coating process, a vacuum evaporation process.

A first conductive layer may be formed on the gate insulation layer 220, and the first conductive layer may be patterned to form the gate electrode 225. The first conductive layer may be formed using a metal such as Al, Ag, W, Cu, Ni, Cr, Mo, Ti, Pt, Ta, Nd, Sc, etc., an alloy of these metals or a nitride of the metal. Alternatively, the first conductive layer may be formed using a transparent conductive material such as ITO, IZO or AZO. The first conductive layer may have a single-layered structure or a multi-layered structure including at least two materials of the metal, the alloy, the metal nitride and the transparent conductive material. The first conductive layer may be obtained by a sputtering process, an ALD process, a pulse lased deposition (“PLD”) process, a vacuum evaporation process, a physical vapor deposition (“PVD”) process, etc.

In exemplary embodiments, the gate electrode 225 may be formed integral with or electrically connected to a gate line of the flexible display device. Where the gate electrode 225 is continuously disposed with the gate line, the gate line and the gate electrode 225 may be formed from the same first conductive layer by the same patterning process to be in a same (single) layer of the flexible display device.

Referring to FIG. 10, p-type or n-type impurities may be implanted into the active layer 210a using the gate electrode 225 as an ion-implantation mask. Accordingly, opposing ends of the active layer 210a substantially not overlapping with the gate electrode 225 may be respectively transformed into a source region 213 and a drain region 215. A portion of the active layer 210a between the source region 213 and the drain region 215 may be defined as a channel region 217.

A first insulating interlayer 230 covering the gate electrode 225 may be formed on the gate insulation layer 220. The first insulating interlayer 230 may be formed using, e.g., silicon oxide, silicon nitride or silicon oxynitride by a CVD process, a PECVD process, a spin coating process, a vacuum evaporation process, etc.

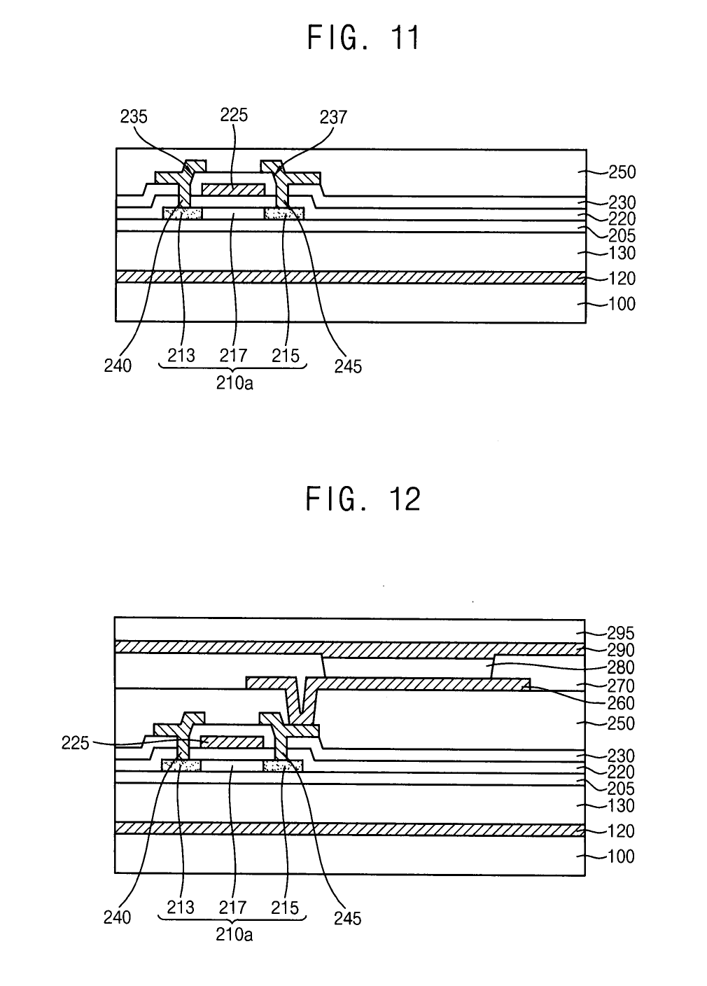

Referring to FIG. 11, a source electrode 240 and a drain electrode 245 electrically connected to the source region 213 and the drain region 215, respectively, may be extended through openings defined in the first insulating interlayer 230 and the gate insulation layer 220. A second insulating interlayer 250 covering the source and drain electrodes 240 and 245 may be formed on the first insulating interlayer 230.

For example, the first insulating interlayer 230 and the gate insulation layer 220 may be partially etched to form a first opening 235 and a second opening 237 at least partially exposing the source region 213 and the drain region 215, respectively. A second conductive layer filling the first and second openings 235 and 237 may be formed on the first insulating interlayer 230, and the second conductive layer may be patterned to obtain the source and drain electrodes 240 and 245.

The second conductive layer may be formed using a metal such as Al, Ag, W, Cu, Ni, Cr, Mo, Ti, Pt, Ta, Nd, Sc, etc., an alloy of these metals or a nitride of the metal. Alternatively, the second conductive layer may be formed using a transparent conductive material such as ITO, IZO or AZO. The second conductive layer may be obtained by a sputtering process, an ALD process, a PLD process, a vacuum evaporation process, a PVD process, etc.

In exemplary embodiments, the source electrode 240 may be formed integral with or electrically connected to a data line of the flexible display device. Where the source electrode 240 is continuously disposed with the data line, the data line and the source electrode 240 may be formed from the same second conductive layer by the same patterning process to be in a same (single) layer of the flexible display device. The drain electrode 245 may also be formed from the same second conductive layer by the same patterning process to be in a same (single) layer of the flexible display device.

The second insulating interlayer 250 may be formed using, e.g., silicon oxide, silicon nitride or silicon oxynitride by a CVD process, a PECVD process, a spin coating process, a vacuum evaporation process, etc. The second insulating interlayer 250 may have a sufficiently thick cross-sectional thickness, and thus the second insulating interlayer 250 may have a substantially leveled or even upper surface. In one exemplary embodiment, a planarization process may be further performed on the upper surface of the second insulating interlayer 250.

Referring to FIG. 12, a light emitting structure including a first electrode 260, a PDL 270, an EML 280 and a second electrode 290 may be formed on the second insulating interlayer 250.

In an exemplary embodiment, for example, the second insulating interlayer 250 may be partially etched to form a third opening at least partially exposing the drain electrode 245. A third conductive layer filling the third opening may be formed on the second insulating interlayer 250, and the third conductive layer may be patterned to form the first electrode 260.

The third conductive layer may be formed using a metal with a relatively low work function such as Al, Ag, W, Cu, Ni, Cr, Mo, Ti, Ta or Nd, an alloy thereof or a nitride thereof. Alternatively, the third conductive layer may be formed using a transparent conductive material such as ITO, IZO, AZO, tin oxide or zinc oxide. The conductive layer may be obtained by a sputtering process, a PVD process, an ALD process, a PLD process, a printing process, etc.

In an exemplary embodiment, for example, a photosensitive material layer including, e.g., an acryl-based resin, a polyimide-based resin or BCB may be formed on the second insulating interlayer 250 and the first electrode 260. The photosensitive material layer may be patterned by an exposure process and a developing process to form the PDL 270. Alternatively, non-photosensitive organic or inorganic layers including, e.g., carbon black may be formed on the second insulating interlayer 250 and the first electrode 260, and then the non-photosensitive organic or inorganic layers may be partially etched to form the PDL 270.

The EML 280 may be formed using a light emitting material for generating different colors of light, for example, a red color of light, a green color of light or a blue color of light. In one exemplary embodiment, the EML 280 may be formed using a combination of light emitting materials for generating a white color of light. The EML 280 may be formed by a spin coating process, a roll printing process, a nozzle printing process, an inkjet printing process, a transfer process using a donor substrate, etc. The EML 280 may be confined by a sidewall of the PDL 270.

In one exemplary embodiment, an HTL may be further formed between the EML 280 and the first electrode 260 using the above mentioned hole transport material. In one exemplary embodiment, an ETL may be further formed on the EML 280 using the above mentioned electron transport material. The HTL and the ETL may be formed by a spin coating process, a roll printing process, a nozzle printing process, an inkjet printing process, a transfer process using a donor substrate, etc.

The second electrode 290 may be formed using a metal such as Li, Ca, LiF/Ca, LiF/Al, Al, Mg, Ag, Cr, W, Mo or Ti, or an alloy thereof. In one exemplary embodiment, the second electrode 290 may be formed using a transparent conductive material such as ITO, IZO, AZO, tin oxide or zinc oxide. The second electrode 290 may be obtained by a sputtering process, a PVD process, an ALD process, a PLD process, a printing process, etc.

The second electrode 290 may be formed continuously on a substantially whole surface of the base substrate layer 130. Alternatively, the second electrode 290 may be patterned in each pixel to be confined by the sidewall of the PDL 270.

In one exemplary embodiment, an encapsulation layer 295 may be further formed using a flexible polyimide on the second electrode 290.

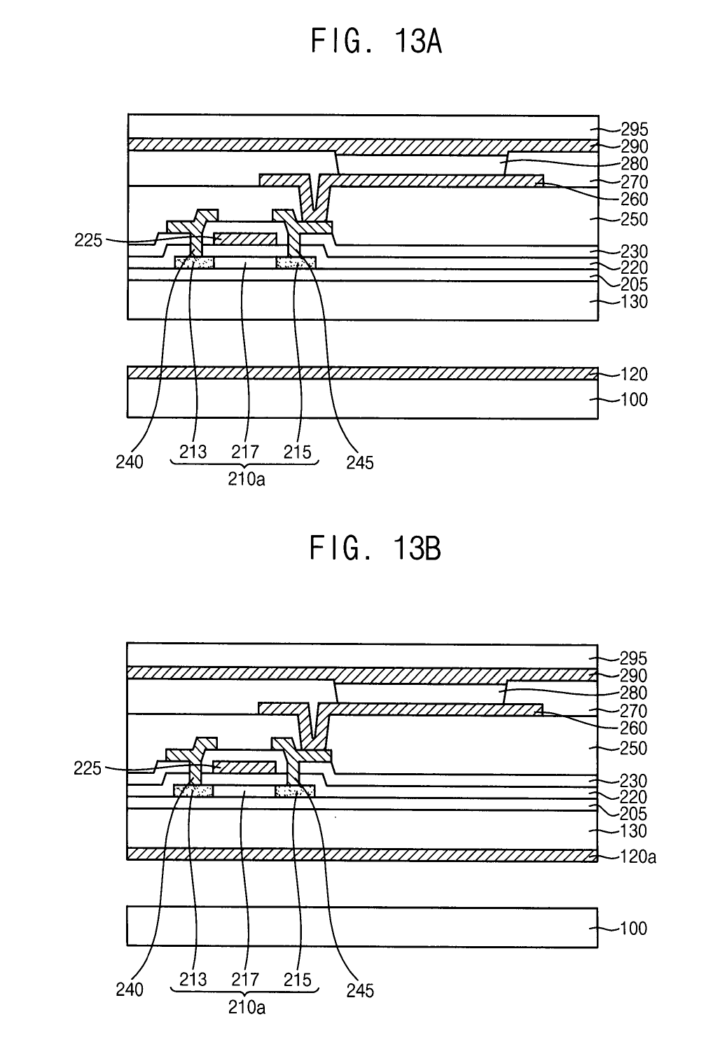

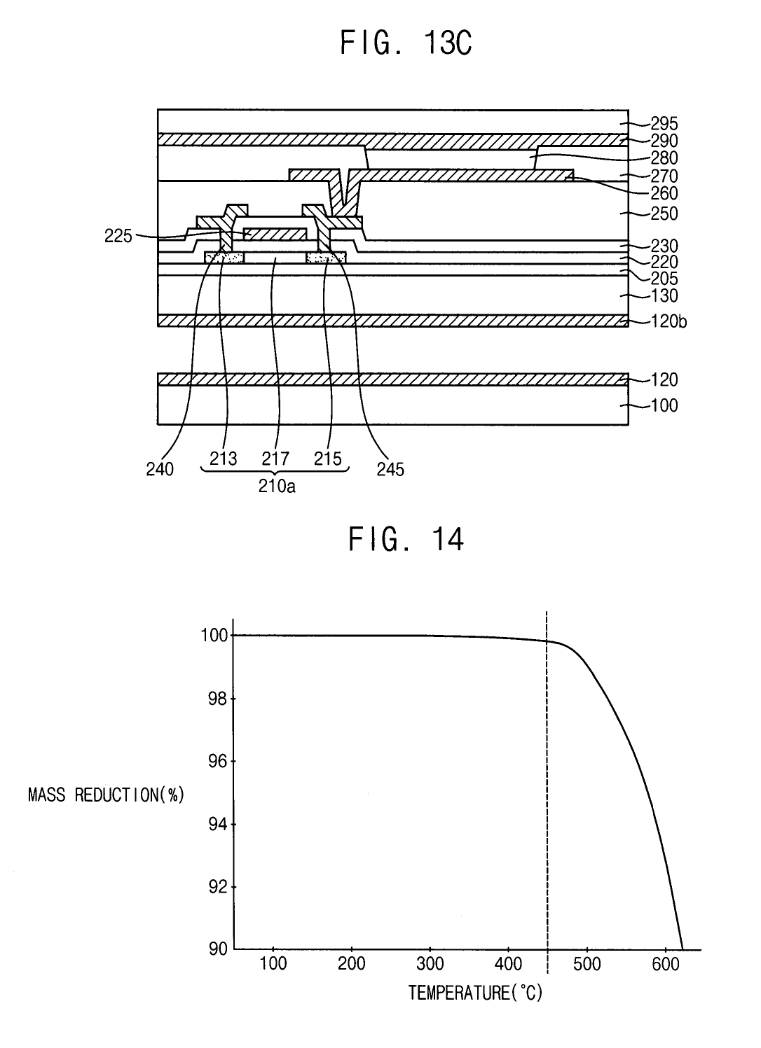

Referring to FIGS. 13A to 13C, processes substantially the same as or similar to those illustrated with reference to FIGS. 5A and 5C may be performed. Accordingly, the base substrate layer 130 including elements thereon may be detached or separated from the carrier substrate 100 to obtain the flexible display device in accordance with exemplary embodiments.

As illustrated in FIG. 13A, the base substrate layer 130 and the elements thereon may be completely separated from the sacrificial layer 120 (see also FIG. 5A).

As illustrated in FIGS. 13B and 13C, a combination of the base substrate layer 130 including the elements thereon and the sacrificial layer 120 may be separated from the carrier substrate 100. Thus, the flexible display device may further include modified polyimide layers 120a and 120b.

As illustrated in FIG. 13B, the sacrificial layer 120 attached to the base substrate layer 130 may be completely separated from the carrier substrate 100 (see also FIG. 5B) to be the modified polyimide layer 120a. As illustrated in FIG. 13C, a portion of the sacrificial layer 120 may be maintained on the carrier substrate 100 and a remaining portion of the sacrificial layer 120 may be separated from the carrier substrate 100 together with the base substrate layer 130 (see also FIG. 5C) to be the modified polyimide layer 120b.

The modified polyimide layer 120b and 120c may cover a lower surface of the base substrate layer 130 to protect the flexible display device from an external environment including, e.g., moisture.

According to exemplary embodiments, the base substrate layer 130 may be formed using polyimide stable at a temperature for a device process, e.g., the LTPS process, so that a flexibility of the base substrate layer 130 may be maintained even after the device process. Additionally, the base substrate layer 130 may be easily separated from the carrier substrate 100 using the sacrificial layer 120 that may include a modified polyimide.

Hereinafter, properties of a sacrificial layer according to exemplary embodiments are described in more detail using Experimental Examples.

### Experimental Example 1

### Evaluation on Mass Reduction of Sacrificial Layers

Polyamic acid precursors were dissolved in NMP to prepare a polyimide precursor composition. The polyimide precursor composition was coated on a glass substrate and thermally cured at 100° C. to form a sacrificial layer including polyimide. The heat treatment was performed on the sacrificial layer by gradually raising the temperature. A mass of the sacrificial layer before the heat treatment and a mass of the sacrificial layer after the heat treatment were measured, and a mass reduction ratio was calculated by a percentage varying the temperature of the heat treatment.

FIG. 14 is a graph showing a mass reduction in percent (%) of a sacrificial layer according to a temperature change in ° C.

Referring to FIG. 14, the mass of the sacrificial layer was maintained substantially constant at an initial mass until the temperature reached about 300° C. Thus, it may be acknowledged that a structure and/or a composition of the sacrificial layer were not substantially changed when the temperature of the heat treatment was less than about 300° C.

As the temperature of the heat treatment exceeds about 300° C., the mass of the sacrificial layer was slightly reduced. When the temperature of the heat treatment reached about 450° C., the mass reduction rate became larger. When the temperature of the heat treatment exceeds about 500° C., the mass of the sacrificial layer was drastically reduced. When the temperature of the heat treatment reached about 600° C., the mass of the sacrificial layer was reduced by about 8% with respect to the initial mass of the sacrificial layer.

Accordingly, the heat treatment may be performed at a temperature greater than about 300° C. in order to obtain the sacrificial layer including a modified polyimide. A critical temperature at which polyimide is transformed into the substantially modified polyimide may be set at about 450° C. If the heat treatment is performed at a temperature greater than about 500° C., polyimide may be transformed into the modified polyimide at a faster rate. However, if the temperature exceeds about 600° C., a loss ratio of the sacrificial layer may be excessively increased.

### Experimental Example 2

### Evaluation on Compositions of Sacrificial Layers

A sacrificial layer was formed on a glass substrate in substantially the same manner as that of Experimental Example 1. A heat treatment was performed on the sacrificial layer at a temperature of about 450° C. in an air atmosphere for 2 hours. A color of the sacrificial layer was changed into a dark yellow color by the heat treatment. Compositions of the sacrificial layer were analyzed by an X-ray photoelectron spectroscopy (“XPS”) method. Specifically, the composition before the heat treatment is represented as Comparative Example, and the composition after the heat treatment is represented as Example. The analyzed results are shown in Table 1 below

TABLE 1

| | Carbon (C) | Nitrogen (N) | Oxygen (O) | Silicon (Si) |
|---|---|---|---|---|
| Comparative | 77.43% | 8.86% | 12.94% | 0.76% |
| Example | | | | |
| Example | 72.51% | 12.2% | 14.79% | 0.49% |

Referring to Table 1, the composition of the sacrificial layer was substantially changed by the heat treatment performed at the critical temperature of about 450° C. as mentioned in Experimental Example 1. Accordingly, polyimide included in the sacrificial layer was transformed into the modified polyimide.

According to one or more exemplary embodiment, a base substrate layer including polyimide and a sacrificial layer including a modified polyimide may be utilized to obtain a flexible substrate stable at a relatively high temperature and easily detachable from a carrier substrate.

The flexible substrate may be implemented to, e.g., a flexible semiconductor device and a flexible display device including a flexible OLED device.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the invention. Accordingly, all such modifications are intended to be included within the scope of the invention as defined in the claims. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

What is claimed is:

1. A method of manufacturing a flexible substrate, comprising:
forming a preliminary sacrificial layer comprising polyimide, on a carrier substrate;
transforming the preliminary sacrificial layer into a sacrificial layer comprising a modified polyimide;
forming a base substrate layer comprising polyimide, on the sacrificial layer;
forming a device structure on the base substrate layer; and
separating a combination of the base substrate layer and the device structure, from the carrier substrate.

2. The method of claim 1, wherein the forming the preliminary sacrificial layer comprises:
coating a polyimide precursor composition on the carrier substrate to form a first coating layer; and
performing a thermal curing process on the first coating layer to form the preliminary sacrificial layer.

3. The method of claim 2, wherein the thermal curing process is performed at a temperature ranging from about 50 degrees Celsius to about 300 degrees Celsius.

4. The method of claim 1, wherein the transforming the preliminary sacrificial layer into the sacrificial layer comprises performing a heat treatment on the preliminary sacrificial layer at a temperature ranging from about 300 degrees Celsius to about 900 degrees Celsius.

5. The method of claim 4, wherein the heat treatment is performed at a temperature ranging from about 300 degrees Celsius to about 600 degrees Celsius.

6. The method of claim 4, wherein the sacrificial layer has a brittleness and a hardness greater than those of the preliminary sacrificial layer.

7. The method of claim 4, wherein the sacrificial layer has an oxygen content greater than that of the preliminary sacrificial layer.

8. The method of claim 4, wherein the sacrificial layer has a coefficient of thermal expansion different from that of the preliminary sacrificial layer.

9. The method of claim 8, wherein the sacrificial layer has a negative coefficient of thermal expansion and the preliminary sacrificial layer has a positive coefficient of thermal expansion.

10. The method of claim 1, wherein the forming the base substrate layer comprises:
coating a second polyimide precursor composition on the sacrificial layer to form a second coating layer; and
thermally curing the second coating layer at a temperature ranging from about 50 degrees Celsius to about 300 degrees Celsius.

11. The method of claim 1, wherein the forming the device structure comprises:
forming an active layer on the base substrate layer; and
performing a crystallization process on the active layer.

12. The method of claim 11, wherein the crystallization process is performed at a temperature ranging from about 200 Celsius to about 500 degrees Celsius.

13. A flexible display device, comprising:
a base substrate layer comprising polyimide;
an electronic device on the base substrate layer;
a light emitting structure electrically connected to the electronic device, on the base substrate layer; and
a modified polyimide layer on a lower surface of the base substrate layer.

14. The flexible display device of claim 13, wherein the modified polyimide layer has a color darker than that of the base substrate layer.

15. The flexible display device of claim 13,
wherein the modified polyimide layer has a brittleness, a hardness and an oxygen content greater than those of the base substrate layer, and
wherein the modified polyimide layer has a coefficient of thermal expansion less than that of the base substrate layer.

16. The flexible display device of claim 13, wherein the electronic device comprises a thin film transistor comprising an active layer.

17. The flexible display device of claim 16, wherein the light emitting structure comprises:
a first electrode electrically connected to the thin film transistor;
an organic light emitting layer on the first electrode; and
a second electrode on the organic light emitting layer.

18. A method of manufacturing a flexible display device, comprising:
forming a preliminary sacrificial layer comprising polyimide, on a carrier substrate;
transforming the preliminary sacrificial layer into a sacrificial layer comprising a modified polyimide;
forming a base substrate layer comprising polyimide, on the sacrificial layer;
forming an electronic device on the base substrate layer; and
forming a light emitting structure electrically connected to the electronic device, on the base substrate layer; and
separating a combination of the base substrate layer, the electronic device and the light emitting structure from the carrier substrate.

19. The method of claim 18, wherein the separating the combination of the base substrate layer, the electronic device and the light emitting structure from the carrier substrate maintains a portion of the sacrificial layer on the lower surface of the base substrate layer.

20. The method of claim 18,
wherein the transforming the preliminary sacrificial layer into the sacrificial layer comprises performing a heat treatment on the preliminary sacrificial layer at a temperature ranging from about 300 degrees Celsius to about 900 degrees Celsius, and
wherein the forming the electronic device on the base substrate layer comprises:
forming a preliminary active layer on the base substrate layer; and
performing a crystallization process on the preliminary active layer at a temperature ranging from about 200 degrees Celsius to about 500 degrees Celsius, to form an active layer.
